(19) United States
(12) Patent Application Publication
(10) Pub. No.: US 2010/0116543 A1
(43) Pub. Date: May 13, 2010

(54) ELECTROMAGNETIC WAVE SUPPRESSOR AND METHOD FOR MANUFACTURING THE SAME

(75) Inventors: Yoshito Ikeda, Tochigi (JP); Norikazu Yamamoto, Tochigi (JP)

Correspondence Address: OSHA LIANG L.L.P., TWO HOUSTON CENTER, 909 FANNIN, SUITE 3500, HOUSTON, TX, 77010, US

(73) Assignee: SONY CHEMICAL & INFORMATION DEVICE CORPORATION, Tokyo (JP)

(21) Appl. No.: 12/597,988

(22) PCT Filed: Dec. 2, 2008
(86) PCT No.: PCT/JP2008/071860

§ 371 Date: Oct. 28, 2009

(30) Foreign Application Priority Data
Apr. 14, 2008 (JP) 2008-104752

(51) Int. Cl. H05K 9/00; B29C 65/42; B29C 65/48

(52) U.S. Cl. 174/388; 264/261; 264/112

(57) ABSTRACT

An electromagnetic wave suppression sheet (1) includes moisture-resistant films (11a), (11b) and an acrylate based polymer gel containing x wt % of an alcohol. The electromagnetic wave suppression sheet (1) is formed by molding so that its thickness (t2) y in mm will be in a region formed by interconnecting a point a (10, 1.0), a point b (10, 3.0) and a point c (20, 1.0), totaling at three points, in an xy coordinate system (x, y). This yields a high non-freezing properties and a high incombustibility of the sheet.

### TECHNICAL FIELD

This invention relates to an electromagnetic wave suppressor that suppresses unnecessary radiations of an electromagnetic wave from e.g. an electronic device.

The present application claims priority rights based on the Japanese Patent Application 2008-104752, filed in Japan on Apr. 14, 2008. The total disclosure of the Patent Application of the senior filing date is to be incorporated herein by reference.

### BACKGROUND ART

In these years, unnecessary radiations of an electromagnetic wave from e.g. an electronic device are becoming of a problem. In particular, in keeping pace with increase in the use of the high-frequency electromagnetic wave, damages or impediments, such as malfunctions of a device or adverse effects to the brain or human bodies, by electromagnetic noise (interferences), are being presented as new environmental problems.

To deal with these problems of EMI (Electromagnetic Interferences), it has become necessary to sufficiently diminish or prevent those adverse reciprocal effects between an electronic device and another device. This may be made possible by suppressing radiations of unnecessary electromagnetic waves from an individual electronic device that might obstruct regular operations of another device or by increasing the resistant power of such another device against an electromagnetic wave emanating from the individual electronic device.

The operating principle of an electromagnetic wave suppressor is that the major portion of the energy of an incident electromagnetic wave is to be converted into the thermal energy within the inside of the electromagnetic wave suppressor. Thus, with the electromagnetic wave suppressor, it is possible to diminish both the energy reflected towards its front side and the energy penetrated towards its rear side.

The loss that occurs in converting the electromagnetic wave into the thermal energy may be classified into electrically conductive loss, dielectric loss and magnetic loss. The quantity of conversion of the electromagnetic wave into the thermal energy may be estimated from these three sorts of loss. In this case, the energy of an electromagnetic wave absorbed by a unit volume P[W/m³] may be expressed, in terms of the electrical field E, a magnetic field H and the frequency f, by the following mathematical expression (1):

$$P = \frac{1}{2} σ {\vert E \vert}^{2} + π f {ɛ}^{″} {\vert E \vert}^{2} + π f {μ}^{″} {\vert H \vert}^{2} \qquad ( 1 )$$

where
electrical conductivity: σ
complex dielectric constant: ε=ε−jε″
complex magnetic permeability: μ=μ′−jμ″

In the above equation (1), the first term, second term and the third term stand for the electrically conductive loss, dielectric loss and the magnetic loss, respectively.

As one of such electromagnetic wave suppressors, a magnetic sheet is used at present mainly for electronic devices. In particular, the magnetic sheet is used as it is bonded on a printed circuit board, a flexible printed circuit (FPC) or on an upper surface of a package. There has so far been developed a large variety of sorts of the magnetic sheet, such as the sheet containing a carbonaceous material, to say nothing of the sheet composed of a mixture of resin with ferrite or magnetic metal powders.

The magnetic sheet is used mainly in two ways. One way of using the magnetic sheet is for absorbing an electromagnetic wave radiated from an antenna source, and another is as a high harmonic filter suppressing that high harmonic noise components superposes on the antenna source.

However, since a magnetic sheet has low optical transparency, it is difficult to use the sheet on a window of a building so that the sheet will contribute to reducing the electromagnetic wave entering a room through a transparent member.

Recently, a NaCl containing gel composition, which is transparent and still operates as an electromagnetic wave suppressor, is attracting attention. See Patent Publication 1, for example. Since the NaCl gel electrolyte has a high dielectric loss, it is expected to show a high electromagnetic wave absorption ratio in the MHz and GHz ranges.
Patent Publication 1: Japanese Patent Publication Laid-Open No. 2006-73991

### DISCLOSURE OF THE INVENTION

### Problem to be Solved by the Invention

Meanwhile, an electronic device is also used in a low temperature environment, such as in a frigid district or in a freezing chamber. Thus, if a gel composition is used as an electromagnetic wave suppressor for an electronic device, there are cases where the moisture of the gel is frozen at a sub-zero temperature. In such case, the dielectric constant of the gel composition is lowered so that the electromagnetic wave suppression function may not be demonstrated.

On the other hand, the electromagnetic wave suppressor converts the electromagnetic wave into the thermal energy, in its inner part, and hence is requested to exhibit the high incombustibility.

The present invention has been proposed in view of the above-described status of the related technique, and provides an electromagnetic wave suppressor having high the non-freezing properties and the high incombustibility, and a method for manufacturing the same.

To solve the above problem, the inventor on the present application has conducted perseverant searches and, as a result, has arrived at a finding that, by prescribing, in an electromagnetic wave suppression sheet containing an acrylate based polymer gel, the concentration of an alcohol in the acrylate based polymer gel and the thickness of the electromagnetic wave suppression sheet, it is possible to develop a high non-freezing properties and a high incombustibility of the electromagnetic wave suppression sheet.

An electromagnetic wave suppressor according to an embodiment of the present invention comprises an electromagnetic wave suppression sheet made up of a first moisture-resistant film, a second moisture-resistant film and an acrylate based polymer gel which is encapsulated in-between the first and second moisture-resistant films. The acrylate based polymer gel contains an x wt % of an alcohol, and a thickness y in mm of the electromagnetic wave suppression sheet is within a region formed on interconnecting a point a (10, 1.0), a point b (10, 3.0) and a point c (20, 1.0), totaling at three points, in an xy coordinate system (x, y).

A method for manufacturing an electromagnetic wave suppressor according to an embodiment of the present invention comprises pouring a composition, composed of x wt % of an alcohol, an acrylate based monomer and a polymerization initiator in-between a first moisture-resistant film and a second moisture-resistant film, hermetically sealing said composition therein, and molding the resulting mass to form an electromagnetic wave suppression sheet made up of the first and second moisture-resistant films and the acrylate-based polymer gel formed on gellation of the composition so that a thickness y in mm of the electromagnetic wave suppression sheet is within a region formed on interconnecting a point a (10, 1.0), a point b (10, 3.0) and a point c (20, 1.0), totaling at three points, in an xy coordinate system (x, y).

According to an embodiment of the present invention, in which the concentration of an alcohol in the acrylate based polymer gel and the thickness of the electromagnetic wave suppression sheet, containing this acrylate based polymer gel, are prescribed to be in respective preset ranges, it is possible to develop a high non-freezing properties and a high incombustibility.

### BRIEF DESCRIPTION OF THE DRAWINGS

FIG. 1 is a cross-sectional view showing an electromagnetic wave suppression sheet according to an embodiment of the present invention.

FIG. 2 is a graph showing solubility curves for sodium nitrate, potassium nitrate, potassium chloride and sodium chloride.

FIG. 3 is a graph showing the relationship between the ethyleneglycol concentration (wt %) and the freezing point (° C.) for sodium chloride concentrations of 1.0 mol/L, 2.0 mol/L, 3.0 mol/L and 4.0 mol/L.

### PREFERRED MODE FOR CARRYING OUT THE INVENTION

A specified embodiment of the present invention is now described in detail with reference to the drawings.

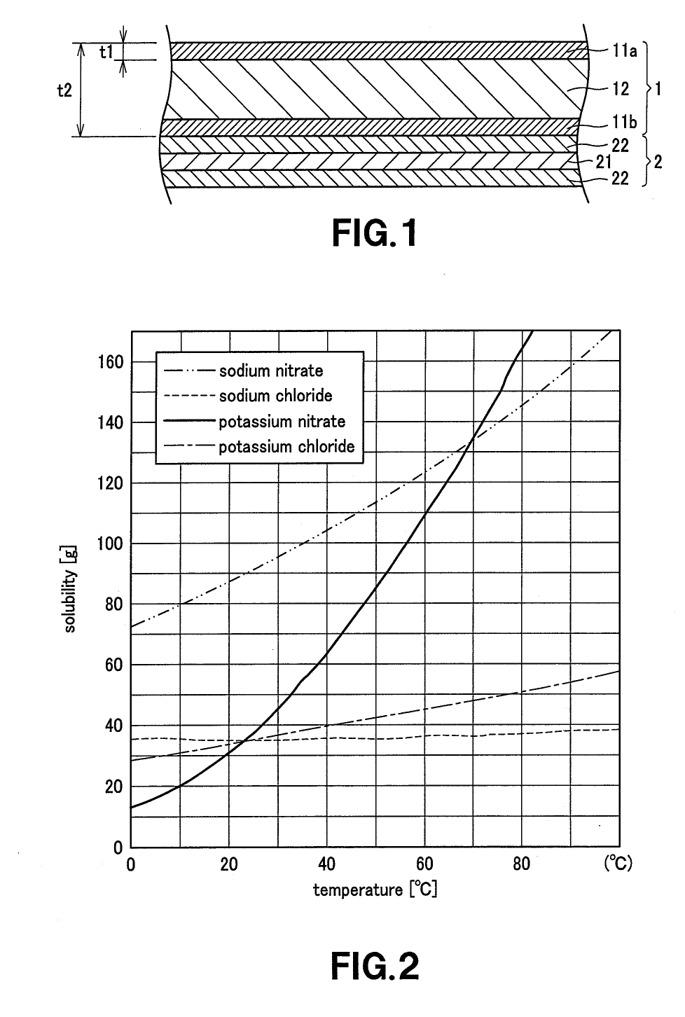

FIG. 1 depicts a cross-sectional view of an electromagnetic wave suppressor of the present embodiment. The electromagnetic wave suppressor includes an electromagnetic wave suppression sheet 1 made up of pair moisture-resistant films 11a, 11b and an electromagnetic wave suppression material 12 sealed in-between the pair moisture-resistant films. That is, the electromagnetic wave suppression sheet 1 has a thickness t2 which is a sum of a thickness t1 of the moisture-resistant film 11a, a thickness t1 of the moisture-resistant film 11b and a thickness of an electromagnetic wave suppression material 12. Meanwhile, the thickness t1 of each of the moisture-resistant films 11a, 11b is on the order of 0.05 to 0.2 mm.

The moisture-resistant films 11a, 11b exhibit a high moisture-resistant properties to prevent evaporation of the moisture contained in the electromagnetic wave suppression material. The moisture-resistant films 11a, 11b are each formed by a plurality of PET (polyethylene terephthalate) films laminated together by thermoplastic resin and a sealing thermoplastic resin material formed thereon as a sealing uppermost surface. Each PET film is provided with a moisture-proofing barrier layer of, for example, a metal oxide. The moisture-resistant films 11a, 11b may be formed e.g. of Cellel, a trade name of a product manufactured by KUREHA CORPORATION.

The electromagnetic wave suppression material 12 is an acrylate-based polymer gel containing an alcohol and an electrolyte. It is observed that the electromagnetic wave suppression function of the gel compound may be maintained in stability even under low-temperature environments because the gel compound contains the alcohol and the electrolyte and hence the freezing point of the gel is low.

As the alcohol, those operating as antifreeze solution are used. The alcohol may be exemplified by a primary alcohol, a secondary alcohol, a ternary alcohol or higher order alcohols, specifically, methanol, ethanol, propanol, butanol, ethyleneglycol (EG), propylene glycol (PG) and pentaerythrytol. Of these, glycols, in particular ethyleneglycol, is most preferred in light of function demonstration and interaction with other compounds.

As the electrolyte, those that induce depression of the solidifying point of the solution may be used. For example, the electrolyte that manifests high solubility in a high dielectric constant polar solvent is preferably used. Such a material having a high dielectric constant ε″ of the second term of the above mathematical expression (1), that stands for the dielectric loss, efficiently absorbs and suppresses an electromagnetic wave in a high frequency range, specifically MHz range or GHz range. Thus, by having the electrolyte solution contained in the gel, the electromagnetic wave absorption efficiency of the gel may be elevated in the high frequency range.

FIG. 2 depicts a graph showing solubility in water of sodium nitrate, potassium nitrate, potassium chloride and sodium chloride. This graph plots the mass in grams of the solutes dissolved in 100 g of a solvent. With potassium chloride and sodium chloride, out of the four compounds, the gradients of the solubility curves are moderate, few probabilities that crystal precipitates with some change in temperature and hence ions may be maintained in stability.

As the electrolytes, strong electrolytes that are completely dissociated into ions in a solution are preferred. These may be enumerated by sodium chloride, potassium chloride, calcium chloride, potassium acetate and calcium acetate. Meanwhile, with calcium acetate, the electromagnetic wave suppression function may be sustained for prolonged time if the compound is used with glycerin exhibiting water retention performance and diffusion performance.

The acrylate based polymer gel has a three-dimensional network structure obtained on addition of a polymerization initiator and a crosslinking agent to an acrylate-based monomer. This three-dimensional network structure is formed by the polymerization initiator initiating a chain reaction of the acrylate-based monomer and by the crosslinking agent playing the role of crosslinking with respect to a portion of the side chain of the acrylate-based polymer material.

With the electromagnetic wave suppression sheet 1, it is desirable that the acrylate-based polymer gel contains an x wt % of an alcohol and that the thickness (t2) y in mm of the electromagnetic wave suppression sheet 1 is within a region defined by interconnecting a point a (10, 1.0), a point b (10, 3.0) and a point c (20, 1.0) in an xy coordinate system (x, y). In this case, the electromagnetic wave suppression sheet 1 exhibits a high non-freezing properties and a high incombustibility.

In addition, the electromagnetic wave suppressor of the present embodiment has an adhesive layer 2 on at least one surface of the electromagnetic wave suppression sheet 1. That is, the adhesive layer 2 is provided on at least one of the moisture-resistant films 11a, 11b.

The adhesive layer 2 is made up of a non-woven fabric 21 and an adhesive 22. On a surface of the adhesive layer 2 opposite to its surface facing the electromagnetic wave suppression sheet 1 is bonded a release PET (polyethylene terephthalate) film. This release film is released for use and the adhesive layer 2 is bonded at a site of generation of the electromagnetic wave to load the electromagnetic wave suppressor on an electronic device. Meanwhile, the thickness of the adhesive layer 2 is on the order of 100 μm to 200 μm.

The non-woven fabric 21 may be endowed with functions, adapted to the object of use or application, by employing a plurality of sorts of feedstock materials or adjusting the shape of the fiber, such as its length or thickness. The feedstock materials may be enumerated by, for example, aramide fibers, glass fibers, cellulose fibers, nylon fibers, vinylon fibers, polyester fibers and polyolefin fibers.

The adhesive 22 is such an adhesive that can be coated on or immersed in a tape-shaped substrate formed of the non-woven fabric 21. The adhesive 22 may be pressured to exhibit fluidity with respect to a material for bonding as well as to exhibit cohesion against releasing. Such adhesive 22 may be exemplified by an acrylic resin based adhesive. For example, an acrylate monomer may be copolymerized with a highly polar monomer to form an adhesive which may then be coated on tissue paper (non-woven fabric) to provide a double-sided tape.

Preferably, a flame retardant, such as hexabromobenzene or antimony trioxide, may be contained in the adhesive 22, whereby the electromagnetic wave suppressor may exhibit a further higher incombustibility.

The electromagnetic wave suppressor thus has a structure in which the electromagnetic wave suppression material 12 is encapsulated by the moisture-resistant films 11a, 11b of the electromagnetic wave suppression sheet 1, thus assuring a sufficient shape retention performance. Moreover, the electromagnetic wave suppressor, in which the electromagnetic wave suppression function may be sustained in stability, may exhibit high flexibility, and hence may be bonded to a structure of a complicated profile, such as a flexible printed circuit board.

The method for manufacturing the electromagnetic wave suppressor of the present embodiment is now explained. Initially, an electrolyte, an alcohol, an acrylate based monomer and a crosslinking agent are dissolved in a solvent. A polymerization initiator is charged into a resulting solution, and the resulting mass is stirred sufficiently.

As the acrylate based monomer, any of mono-functional acrylates, such as methyl acrylate, ethyl acrylate, aromatic acrylate or acrylamide, may be used. In particular, acrylamide is most preferred in light of its interaction with the alcohols and electrolytes.

As the crosslinking agent, di-functional acrylate, tri-functional acrylate or higher functional acrylate, for example, may be used. Of these, N,N′-alkylenebis acrylamide is preferred, and in particular, N,N′-methylenebis acrylamide, is most preferred in light of interaction with the alcohol and with the electrolyte. Further, as regards a crosslinking method, such a method that uses thermal crosslinking and optical crosslinking in combination, may be used.

As regards the polymerization initiator, for example, a radical initiator may be used. In particular, an azo-based initiator or a peroxide-based initiator is most preferred. Of these, ammonium peroxodisulfate is most preferred in light of its interaction with the alcohol and with the electrolyte.

Then, the stirred mixed solution is charged into a vacuum oven which was depressurized at ambient temperature, and oxygen in the mixed solution is extracted by degassing operation.

The moisture-resistant films 11a, 11b were cut into a plurality of predetermined size pieces. Two of these pieces were placed facing each other, with their sealing surfaces which are thermoplastic resin forming surfaces and the three sides, except injecting opening for a solution, were laminated together, using an impact sealer, at a predetermined temperature, to form a pouch of the moisture-resistant films 11a, 11b.

The so formed pouch of the moisture-resistant films 11a, 11b was introduced into a thickness retention jig, not shown, and the mixed solution was poured and charged into the pouch. As an excess overflowing portion of the mixed solution was extruded by the impact sealer, the injection opening of the pouch of the moisture-resistant films 11a, 11b was closed to form a sheet of a predetermined thickness.

The sheet of the predetermined thickness, clamped by the thickness retention jig, was charged into an oven and the reaction of polymerization and crosslinking of the acrylate based monomer was carried out within the sheet material to formulate the electromagnetic wave suppression material 12 of the acrylamide-based high polymer gel to mold the electromagnetic wave suppression sheet 1.

As an example of the acrylamide-based polymer gel, acrylamide may be used as the acrylate monomer, and N,N′-methylenebis acryamide may be used as crosslinking agent. Also, ammonium peroxodisulfate may be used as a polymerization initiator, and sodium chloride may be used as an electrolyte. Ethyleneglycol may be used as an alcohol. In this case, acrylamide is polymerized by ammonium peroxodisulfate, at the same time as N,N′-methylenebis acrylamide, as the crosslinking agent, is bonded to a part of the side chain of acrylamide to generate polyacylamide having a three-dimensional network structure. This polyacylamide absorbs the sodium chloride solution and ethyleneglycol and becomes swollen to generate the polyacrylamide gel.

The electromagnetic wave suppression sheet 1 is taken out of the oven, and the non-woven fabric 21, as a tape-shaped substrate, is arranged on at least one of its surfaces so that the adhesive 22 is coated on or immersed in the non-woven fabric 21 to form an adhesive layer 2. A PET release film is then bonded on the adhesive layer 2 to produce the electromagnetic wave suppressor.

With the embodiment of the present application, the electromagnetic wave suppression sheet 1 with a thickness (t2) y in mm, made up of the moisture-resistant films 11a, 11b and the acrylate-based polymer gel containing an x wt % of the alcohol, is molded so that the thickness (t2) y in mm of the electromagnetic wave suppression sheet 1 is within a region defined by interconnecting a point a (10, 1.0), a point b (10, 3.0) and a point c (20, 1.0) in an xy coordinate system (x, y). In this manner, the electromagnetic wave suppression sheet 1 exhibiting a high non-freezing properties and a high incombustibility may be produced.

Moreover, by adjusting the amounts of addition of the electrolyte and the alcohol, the electromagnetic wave suppression function may be demonstrated in stability without the gel becoming frozen even under a low temperature environment. In particular, in adding not less than 10 wt % and not more than 20 wt % of the alcohol, the electrolyte is added in an amount not less than 3.0 mol/L, so that the electromagnetic wave suppression material 12 with a gel freezing point not higher than −20° C. may now be produced. In this manner, the electromagnetic wave suppression material 12 may demonstrate its electromagnetic wave suppressing function in stability without the gel becoming frozen even under a low temperature environment, such that, in Japan, the electromagnetic wave suppression material may be used in any place, both indoors and outdoors, in any seasons of the year.

### Example

An Example of the present invention is now described. It is observed that the present Example may be modified in many ways without departing from the purport of the invention.

### <Preparation of Electromagnetic Wave Suppression Sheet>

The method for fabrication of an electromagnetic wave suppression sheet, encapsulated with moisture-resistant films, is now described.

To pure water (68.62 g) were added sodium chloride (8.01 g, manufactured by KANTO CHEMICAL CO. INC.), ethyleneglycol (17.16 g, manufactured by KANTO CHEMICAL. CO. INC.), acrylamide (6.10 g, manufactured by WAKO PURE CHEMICAL INDUSTRIES, Ltd.) and N,N′-methylenebis acrylamide (0.07 g, manufactured by WAKO PURE CHEMICAL INDUSTRIES, Ltd.). The resulting mass was stirred by a stirrer until the compounds were dissolved completely. The resulting solution was added by ammonium peroxodisulfate (0.04 g, manufactured by WAKO PURE CHEMICAL INDUSTRIES, Ltd.) as polymerization initiator. The resulting mass was sufficiently stirred in a stirrer until ammonium peroxodisulfate was dissolved completely.

As a result, the concentration of the mixed solution was 2.0 mol/L of sodium chloride, 20 wt % of ethyleneglycol, 1.0 mol/L of acrylamide, 0.5 mol/L of N,N′-methylenebis acrylamide and 0.2 mol/L of ammonium peroxodisulfate.

Then, the stirred mixed solution was charged into a vacuum oven which is depressurized at ambient temperature, and oxygen in the mixed solution was extracted by way of a defoaming operation.

The moisture-resistant films (CELLEL, a trade name of a product manufactured by KUREHA CORPORATION) were cut to a predetermined size pieces, and there pieces were placed facing each other with their sealing surfaces, as thermoplastic resin forming surfaces, the three sides except a injecting opening for a solution, were laminated together, using an impact sealer, to form a pouch of the moisture-resistant films.

The formed pouch of the moisture-resistant films was introduced into a thickness retention jig, made up of a glass substrate and a spacer of an aluminum sheet, having a thickness sufficient for the electromagnetic wave suppression sheet. The mixed solution was then poured into the inside of the pouch of the moisture-resistant films and the mixed solution was poured and charged into the pouch. As an excess overflowing portion of the mixed solution was extruded by the impact sealer, the injection opening of the pouch of the moisture-resistant film was closed to form an electromagnetic wave suppression sheet.

The sheet which was charged the mixed solution, clamped by the thickness retention jig, was charged into an oven which was set 60 degrees and the reaction of polymerization and crosslinking of the acrylate monomer was carried out within the sheet material to formulate a polyacrylamide gel. This completes an electromagnetic wave suppression sheet. The electromagnetic wave suppression sheet, in which has been sealed the electromagnetic wave suppression material, was taken out of the oven.

### <Measurement of Depression of Freezing Point of the Electromagnetic Wave Suppression Material>

16 kinds of electromagnetic wave suppression sheets (samples 1 to 16) were fabricated as the concentration of sodium chloride [mol/L] and that of ethyleneglycol [wt. %] were varied, and measurement was made of the freezing points of the samples. The following Table 1 shows the values of the concentration of sodium chloride [mol/L], that of ethyleneglycol [wt. %] and the freezing point [° C.] of the samples 1 to 16.

| | Concentration of | EG concentration | Freezing point |
|---|---|---|---|
| | NaCl (mol/L) | (wt %) | (° C.) |
| Sample 1 | 1.0 | 10 | −7.5 |
| Sample 2 | 1.0 | 15 | −12.0 |
| Sample 3 | 1.0 | 20 | −15.0 |
| Sample 4 | 1.0 | 25 | −18.0 |
| Sample 5 | 2.0 | 10 | −12.5 |
| Sample 6 | 2.0 | 15 | −17.5 |
| Sample 7 | 2.0 | 20 | −21.5 |
| Sample 8 | 2.0 | 25 | −25.0 |
| Sample 9 | 3.0 | 10 | −19.0 |
| Sample 10 | 3.0 | 15 | −22.5 |
| Sample 11 | 3.0 | 20 | −26.0 |
| Sample 12 | 3.0 | 25 | −31.0 |
| Sample 13 | 4.0 | 10 | −26.5 |
| Sample 14 | 4.0 | 15 | −30.0 |
| Sample 15 | 4.0 | 20 | −37.5 |
| Sample 16 | 4.0 | 25 | −44.0 |

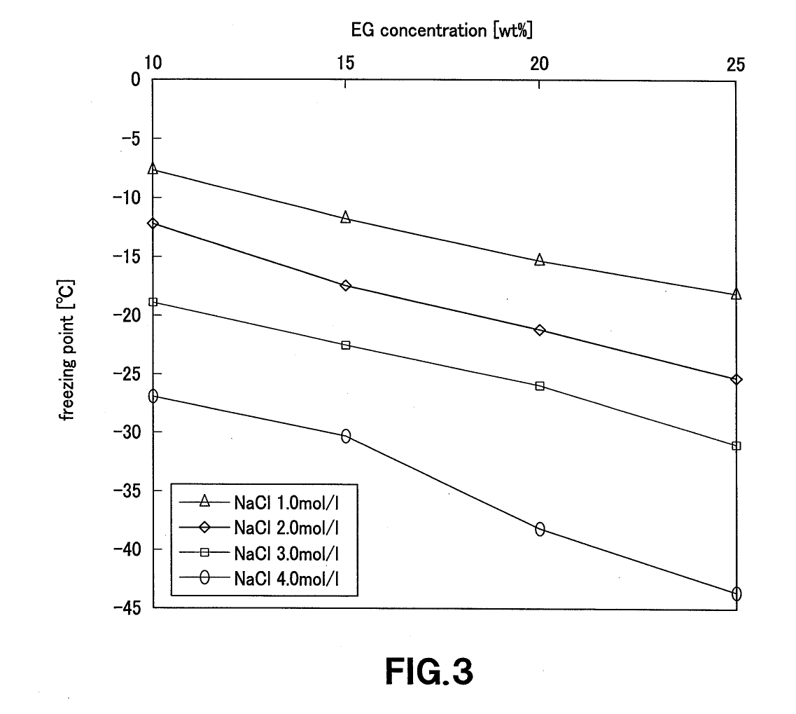

FIG. 3 shows the relationship between the concentration of ethyleneglycol [wt. %] and the freezing point [° C], for the concentrations of sodium chloride of 1.0 mol/L, 2.0 mol/L, 3.0 mol/L and 4.0 mol/L, based on the values shown in Table 1.

In FIG. 3, the freezing point of polycrylamide gel was depressed with rise in the concentration of sodium chloride. On the other hand, the freezing point of polycrylamide gel was depressed with rise in the concentration of ethyleneglycol [wt. %].

As may be seen from FIG. 3, with the concentration of sodium chloride of 1.0 mol/L, the freezing point of the polycrylamide gel was not depressed to below −20° C. for any of the values of the concentration of ethyleneglycol ranging between 10 and 25 wt %.

### <Measurement of Combustion Retardant Property of Electromagnetic Wave Suppressor>

A test for combustion of an electromagnetic wave suppressor was conducted in accordance with UL (Underwriter Laboratories Inc.) flame-resistant test standard UL94. A burner flame was applied to a lower end of a strip-shaped test piece (125±5 mm×13±5 mm×thickness in mm) set upright and was kept for ten seconds. The burner flame was then separated from the test piece. When the flame was extinguished, the burner flame was immediately applied for further ten seconds and was then separated to give a decision. The decision was given on the basis of the duration of combustion with flame after end of first and second contacts of the flame with the test piece, sum of the duration of combustion with flame and the duration of combustion without flame after end of the second contact of the flame with the test piece, sum of the duration of combustion with flame of five test pieces and the presence/absence of the combustion drips. A decision on V0 was given when the combustion for the first and second times was completed within 10 seconds, while that on V1, V2 was given when the combustion for the first and second times was completed within 20 seconds. A decision on V0 and that on V1 and V2 were given when the sum of the time duration combustion with flame and the time duration combustion without flame until extinguishment was within 30 seconds and within 60 seconds, respectively. Further, a V0 decision and that on V1 and V2 were given when the sum of the time durations of combustion of five test pieces was less than 50 seconds and less than 250 seconds, respectively. Meanwhile, combustion drips were tolerated only for V2 and none of test pieces is allowed to be burned off.

The test piece formed only of an electromagnetic wave suppression sheet, and which was manufactured by the above manufacturing method, was burned off Thus, a combustion test was conducted on a test piece on one side of which was provided an incombustible adhesive layer to carry out a test for combustion.

As an incombustible adhesive layer, a pressure-sensitive double-sided adhesive tape UT1515, a trade name of a product manufactured by SONY CHEMICAL & INFORMATION DEVICE CORPORATION, approximately 150 μm in thickness, was used. This pressure-sensitive double-sided adhesive tape contains Conlon I, a trade name of a product manufactured by SHIN FUJI PAPER COMPANY LIMITED, with a thickness of approximately 40 μm, as a non-woven fabric, 30 to 40 wt % of hexabromobenzene (HBB: C₆Br₆), as a flame retardant, and 5 to 10 wt. % of antimony trioxide (Sb₂O₃).

### [Test Piece 1]

A strip-shaped electromagnetic wave suppression sheet (125±5 mm×13±0.5 mm×0.5 mm in thickness) was produced by the above manufacturing method, with the concentration of sodium chloride of 3 mol/L and with that of ethyleneglycol of 10 wt. %. A pressure-sensitive double-sided adhesive tape UT1515 was bonded to an entire surface of the electromagnetic wave suppression sheet to prepare a test piece 1.

### [Test Piece 2]

A test piece 2 was manufactured in the same way as in the method for manufacturing the test piece 1 except setting the thickness of the strip-shaped electromagnetic wave suppression sheet to 1.0 mm.

### [Test Piece 3]

A test piece 3 was manufactured in the same way as in the method for manufacturing the test piece 1 except setting the thickness of the strip-shaped electromagnetic wave suppression sheet to 2.0 mm.

### [Test Piece 4]

A test piece 4 was manufactured in the same way as in the method for manufacturing the test piece 1 except setting the thickness of the strip-shaped electromagnetic wave suppression sheet to 3.0 mm.

### [Test Piece 5]

A test piece 5 was manufactured in the same way as in the method for manufacturing the test piece 1 except setting the concentration of ethyleneglycol to 20 wt %.

### [Test Piece 6]

A test piece 6 was manufactured in the same way as in the method for manufacturing the test piece 1 except setting the concentration of ethyleneglycol to 20 wt % and setting the thickness of the strip-shaped electromagnetic wave suppression sheet to 1.0 mm

### [Test Piece 7]

A test piece 7 was manufactured in the same way as in the method for manufacturing the test piece 1 except setting the concentration of ethyleneglycol to 20 wt % and setting the thickness of the strip-shaped electromagnetic wave suppression sheet to 2.0 mm

### [Test Piece 8]

A test piece 8 was manufactured in the same way as in the method for manufacturing the test piece 1 except setting the concentration of ethyleneglycol to 20 wt % and setting the thickness of the strip-shaped electromagnetic wave suppression sheet to 3.0 mm.

### [Test Piece 9]

A test piece 9 was manufactured in the same way as in the method for manufacturing the test piece 1 except setting the concentration of ethyleneglycol to 20 wt %, setting the thickness of the strip-shaped electromagnetic wave suppression sheet to 1.0 mm and providing an adhesive layer that is formed of the same resin as UT1515 and that is not provided with the non-woven fabric as the substrate.

### [Test Piece 10]

A test piece 10 was manufactured in the same way as in the method for manufacturing the test piece 1 except setting the concentration of ethyleneglycol to 20 wt %, setting the thickness of the strip-shaped electromagnetic wave suppression sheet to 2.0 mm and providing an adhesive layer that is formed of the same resin as UT1515 and that is not provided with the non-woven fabric as the substrate.

### [Test Piece 11]

A test piece 11 was manufactured in the same way as in the method for manufacturing the test piece 1 except setting the concentration of ethyleneglycol to 10 wt %, setting the thickness of the strip-shaped electromagnetic wave suppression sheet to 3 0 mm and providing an adhesive layer that is formed of the same resin as UT1515 and that is not provided with the non-woven fabric as the substrate.

It is observed that, with the concentration of ethyleneglycol of 30 wt %, curing defects of the polyacrylamide gel occurred, such that an electromagnetic wave suppression sheet of a predetermined thickness could not be produced. On the other hand, a test piece with a thickness not less than 3.5 mm could not be produced because of the constraint of the real manufacturing device used.

Table 2 shows the results of the combustion test for the test pieces 1 to 8 and Table 3 shows those for the test pieces 9 to 11.

TABLE 2

| | 0.5 mm | 1.0 mm | 2.0 mm | 3.0 mm |
|---|---|---|---|---|
| 10 wt % | 1: burned off | 2: V1 | 3: V1 | 4: V0 |
| 20 wt % | 5: burned off | 6: V1 | 7: burned off | 8: burned off |
| 30 wt % | — | — | — | — |

TABLE 3

| | 0.5 mm | 1.0 mm | 2.0 mm | 3.0 mm |
|---|---|---|---|---|
| 10 wt % | | | | 11: burned off |
| 20 wt % | | 9: burned off | 10: burned off | |
| 30 wt % | — | — | — | — |

As may be seen from this Table 2, the incombustibility could be verified for the test pieces 2 to 4 and 6. With the test piece 1, 0 5 mm in thickness, out of the test pieces 1 to 4, having the concentration of ethyleneglycol of 10 wt %, the amount of the moisture was small because of the smaller quantity of the gel. This presumably accounts for the absence of the incombustibility in the test piece 1. The test pieces 2 to 4 manifested the incombustibility of V1, V2 and V0, respectively, possibly due to the fact that the thickness was not less than 1.0 mm and hence much water was contained in the gel composition.

Out of the test pieces 5 to 8, with the concentration of ethyleneglycol of 20 wt %, the test piece 5 with the thickness of 0 5 mm failed to manifest the incombustibility, possibly because its gel content was small and hence its water content was small. On the other hand, the test piece 6, with the thickness of 1.0 mm, demonstrated the incombustibility of V1. However, the test pieces 7, 8, with the thickness not less than 2.0 mm, burned off and thus failed to demonstrate the incombustibility. This is possibly due to the fact that, with increase in the thickness, the amount of ethyleneglycol contained in the gel composition also increased.

That is, by carrying out molding so that the thickness y in mm of the electromagnetic wave suppression sheet, made up of a moisture-resistant film and a polyacryate gel containing x wt % of ethyleneglycol, will be within a region delimited by interconnecting three points, namely a point a (10, 1.0), a point b (10, 3.0) and a point c (20, 1.0) in an xy coordinate system (x, y), it is possible to develop a high non-freezing properties and a high incombustibility.

On the other hand, the test pieces 9 to 11, each provided with the adhesive layer that is formed of the same resin as UT1515 and that is not provided with the non-woven fabric as the substrate, all burned off and thus failed to demonstrate the incombustibility, as shown in Table 3. It has thus been seen that, by providing the adhesive layer that includes a non-woven fabric and a combustion retardant adhesive, a high incombustibility can be developed, as apparent on comparison of the test pieces 6 and 9 or the test pieces 4 and 11.

1. An electromagnetic wave suppressor comprising an electromagnetic wave suppression sheet including a first moisture-resistant film, a second moisture-resistant film and an acrylate based polymer gel which is encapsulated in-between said first and second moisture-resistant films; wherein:
said acrylate based polymer gel contains x wt % of an alcohol; and wherein a thickness y in mm of said electromagnetic wave suppression sheet is within a region formed on interconnecting a point a (10, 1.0), a point b (10, 3.0) and a point c (20, 1.0), totaling at three points, in an xy coordinate system (x, y).

2. The electromagnetic wave suppressor according to claim 1, wherein said alcohol is at least one of methanol, ethanol, propanol, butanol, ethyleneglycol, propylene glycol and pentaerythrytol.

3. The electromagnetic wave suppressor according to claim 1, wherein said acrylate based polymer gel contains electrolyte and said electrolyte is at least one of sodium chloride, potassium chloride, calcium chloride, potassium acetate and calcium acetate.

4. The electromagnetic wave suppressor according to claim 3, wherein said electrolyte is added in a quantity of not less than 3.0 mol/L to a pre-cure composition of said acrylate based polymer gel.

5. The electromagnetic wave suppressor according to claims 1, further comprising:
a non-woven fabric based adhesive layer on at least one of a surface of said first moisture-resistant film and a surface of said second moisture-resistant film.

6. The electromagnetic wave suppressor according to claim 5, wherein said adhesive layer contains hexabromobenzene and antimony trioxide.

7. A method for manufacturing an electromagnetic wave suppressor, comprising:
pouring a composition, composed of x wt % of an alcohol, an acrylate based monomer and a polymerization initiator in-between a first moisture-resistant film and a second moisture-resistant film;
hermetically sealing the composition therein; and
molding the resulting mass to form an electromagnetic wave suppression sheet made up of said first and second moisture-resistant films and an acrylate-based polymer gel formed on gellation of said composition so that a thickness y in mm of the electromagnetic wave suppression sheet is within a region formed on interconnecting a point a (10, 1.0), a point b (10, 3.0) and a point c (20, 1.0), totaling at three points, in an xy coordinate system (x, y).

8. The method according to claim 7 wherein said alcohol is at least one of methanol, ethanol, propanol, butanol, ethyleneglycol, propylene glycol and pentaerythrytol.

9. The method according to claim 7 wherein said composition includes an electrolyte and wherein said electrolyte is at least one of sodium chloride, potassium chloride, calcium chloride, potassium acetate and calcium acetate.

10. The method according to claim 9 wherein an electrolyte is added in an amount of not less than 3.0 mol/L to said composition.

11. The method according to claim 7 wherein, after molding said electromagnetic wave suppression sheet, a non-woven fabric based adhesive layer is formed on at least one of a surface of said first moisture-resistant film and a surface of said second moisture-resistant film.

12. The method according to claim 11 wherein said adhesive layer contains hexabromobenzene and antimony trioxide.

13. The electromagnetic wave suppressor according to claim 2, further comprising:
a non-woven fabric based adhesive layer on at least one of a surface of said first moisture-resistant film and a surface of said second moisture-resistant film.

14. The electromagnetic wave suppressor according to claim 3, further comprising:
a non-woven fabric based adhesive layer on at least one of a surface of said first moisture-resistant film and a surface of said second moisture-resistant film.

15. The electromagnetic wave suppressor according to claim 4, further comprising:
a non-woven fabric based adhesive layer on at least one of a surface of said first moisture-resistant film and a surface of said second moisture-resistant film.

16. The method according to claim 8 wherein, after molding said electromagnetic wave suppression sheet, a non-woven fabric based adhesive layer is formed on at least one of a surface of said first moisture-resistant film and a surface of said second moisture-resistant film.

17. The method according to claim 9 wherein, after molding said electromagnetic wave suppression sheet, a non-woven fabric based adhesive layer is formed on at least one of a surface of said first moisture-resistant film and a surface of said second moisture-resistant film.

18. The method according to claim 10 wherein, after molding said electromagnetic wave suppression sheet, a non-woven fabric based adhesive layer is formed on at least one of a surface of said first moisture-resistant film and a surface of said second moisture-resistant film
